(19) United States
(12) Patent Application Publication
(10) Pub. No.: US 2026/0333970 A1
(43) Pub. Date: Oct. 22, 2026

(54) LIGHT EMITTING DEVICE INCLUDING LED DIE HAVING PORTIONS LOCATED IN ADJACENT PIXELS AND METHOD OF MAKING SAME

(71) Applicant: SAMSUNG ELECTRONICS CO., LTD., Suwon-si (KR)

(72) Inventors: Ansel S. REED, Milpitas, CA (US); Saket CHADDA, Milpitas, CA (US)

(73) Assignee: SAMSUNG ELECTRONICS CO., LTD., Suwon-si (KR)

(21) Appl. No.: 19/116,909

(22) PCT Filed: Sep. 27, 2023
(86) PCT No.: PCT/US2023/033836

§ 371 Date: Mar. 28, 2025

Related U.S. Application Data
(60) Provisional application No. 63/377,603, filed on Sep. 29, 2022.

(51) Int. Cl. H10H 29/30; H10H 29/01

(52) U.S. Cl. CPC H10H 29/352; H10H 29/012

(57) ABSTRACT

A light emitting device includes a backplane, a plurality of light emitting diode (LED) dies mounted on the backplane, such that each of the LED dies includes a plurality of LEDs, and a pixel containing adjacent micro-LEDs of the plurality of LEDs located in adjacent LED dies of the plurality of LED dies.

### FIELD

The present invention relates to light emitting devices, and particularly to a light emitting device including a light emitting diode (LED) die having different portions located in different adjacent pixels, and methods of fabricating the same.

### BACKGROUND

As the size of light emitting devices (e.g., displays) decreases, a size of micro-LEDs (e.g., LEDs having a size in the micron or sub-micron range) used in the light emitting devices may also decrease in order to maintain a high resolution. As the size of micro-LEDs decreases, it may become more difficult to manufacture the micro-LEDs, both on the wafer fabrication and mass transfer sides of processing.

### SUMMARY

According to an aspect of the present disclosure, a light emitting device includes a backplane, a plurality of light emitting diode (LED) dies mounted on the backplane, such that each of the LED dies includes a plurality of LEDs, and a pixel containing adjacent micro-LEDs of the plurality of LEDs located in adjacent LED dies of the plurality of LED dies.

According to another aspect of the present disclosure, a method of forming a light emitting device comprises providing a backplane, providing a plurality of light emitting diode (LED) dies, each comprising a plurality of LEDs, and mounting the plurality of LED dies on the backplane such that adjacent LEDs of the plurality of LEDs in adjacent LED dies of the plurality of LED dies constitute a pixel.

### BRIEF DESCRIPTION OF THE DRAWINGS

FIG. 1A is a plan view (e.g., top-down view showing a layout overview) of a light emitting device according to one or more embodiments.

FIG. 1B is a top perspective view of the left half of the light emitting device in FIG. 1A, according to one or more embodiments.

FIG. 1C is a vertical cross-sectional view of the light emitting device along the line I-I′ in FIG. 1A, according to one or more embodiments.

FIG. 1D is a bottom perspective view of the LED die according to one or more embodiments.

FIG. 2A is a schematic diagram of a pixel that may include a portion of four adjacent LED dies in the light emitting device according to one or more embodiments.

FIG. 2B is a schematic diagram of a portion of a pixel array that may be included in the display module of the backplane according to one or more embodiments.

FIG. 3A is a schematic diagram of a defect repair system for repairing a defective micro-LED in the light emitting device according to one or more embodiments.

FIG. 3B is a flow chart illustrating a method of repairing a defective micro-LED according to one or more embodiments.

FIG. 4 is a schematic diagram of the light emitting device having an alternative layout pattern for the LED dies according to one or more embodiments.

FIG. 5 is a vertical cross-sectional view of a backplane, according to one or more embodiments.

FIG. 6A is a vertical cross-sectional view of an exemplary intermediate structure including an LED die base layer formed on a substrate, according to one or more embodiments.

FIG. 6B is a vertical cross-sectional view of an exemplary intermediate structure including various layers of a micro-LED on the LED die base layer, according to one or more embodiments.

FIG. 6C is a vertical cross-sectional view of an exemplary intermediate structure including micro-LEDs on the LED die base layer, according to one or more embodiments.

FIG. 6D is another vertical cross-sectional view of an exemplary intermediate structure including micro-LEDs on the LED die base layer, according to one or more embodiments.

FIG. 6E is vertical cross-sectional view of an exemplary intermediate structure including the LED die mounted on the backplane and separated from the substrate, according to one or more embodiments.

FIG. 7 is vertical cross-sectional view of an exemplary intermediate structure including the LED die mounted on the backplane after separation from the substrate, according to one or more embodiments.

FIG. 8 is a flow chart illustrating a method of making the light emitting device according to one or more embodiments.

### DETAILED DESCRIPTION

As discussed above, the embodiments of the present disclosure are directed to light emitting devices, and particularly to a light emitting device including a LED die having different portions located in different adjacent pixels, and methods of fabricating the same, the various aspects of which are discussed herein in detail. The drawings are not necessarily drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The same reference numerals refer to the same element or similar element. Unless otherwise indicated, elements having the same reference numerals are presumed to have the same composition. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a “layer” refers to a continuous portion of at least one material including a region having a thickness. A layer may consist of a single material portion having a homogeneous composition, or may include multiple material portions having different compositions.

As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁵ S/cm. As used herein, a “semiconducting material” refers to a material having electrical conductivity in the range from 1.0×10⁻⁵ S/cm to 1.0×10⁵ S/cm. As used herein, a “metallic material” refers to a conductive material including at least one metallic element therein. All measurements for electrical conductivities are made at the standard condition.

A light emitting device, such as a display device (e.g., direct view display) can be formed from an ordered array of pixels. Each pixel can include a set of subpixels that emit light at a respective peak wavelength. For example, a pixel can include a red subpixel, a green subpixel, and a blue subpixel. Each subpixel can include one or more light emitting diodes that emit light of a particular wavelength. Each pixel may be driven by a backplane circuit such that any combination of colors within a color gamut may be shown on the display for each pixel. The display (e.g., display panel) can be formed by a process in which light emitting diode (LED) subpixels are soldered to, or otherwise electrically attached to, a bonding pad on a surface of a backplane. The bonding pad may be electrically driven by the backplane circuit and other driving electronics.

In a typical red/green/blue (RGB) mass transfer technique, one micro-LED may be transferred per one sub-pixel. Thus, a size of the micro-LED size may shrink with a decrease in sub-pixel size. Common mass transfer techniques, such as elastomeric stamps and electrostatic pick-up, may struggle to achieve high yields at micro-LED sizes below about 5 microns and sub-pixel pitches below about 10 microns.

One or more embodiments of the present disclosure may include a light emitting device (e.g., a RGB micro-LED display) that may help to alleviate the problems of typical light emitting devices (e.g., displays) and methods of fabricating the light emitting device. The light emitting device may include, for example, a plurality of LED dies (e.g., micro-monolithic micro-LEDs) that may each include a plurality of micro-LEDs. As used herein, a micro-LED has a width and/or length of 20 microns or less, such as 5 microns or less, for example 500 nm to 3 microns. The light emitting device may be referred to as a micro-monolithic micro-LED display (e.g., a micro-monolithic RGB micro-LED display). In at least one embodiment, the micro-monolithic micro-LEDs may each include four separate mesas that may be connected to separate backplane electrical connections and form four adjacent sub-pixels located in four separate adjacent pixels.

Generally, a larger micro-LED may be easier to transfer than a smaller micro-LED. To address the difficulty of transferring small micro-LEDs (e.g., micro-LEDs of sizes that are sub-20 microns, such as 5 microns or less), one or more embodiments may divide the backplane facing portion of the larger LED die (which may be easy to transfer) into smaller sub-units. The sub-units of the larger LED die may be located in multiple adjacent pixels such that one LED die can be separately addressed by the backplane as multiple individual micro-LED subpixels. This may allow a high pixel-per-inch (PPI) resolution to be maintained while transferring larger LED die with large wafer-level pitches to the backplane.

For example, in at least one embodiment, the transferred LED die size (e.g., length and width for square die) and pitch may be 7 microns and 32 microns, respectively, to achieve a subpixel size of 3 microns and pixel pitch of 16 microns. To achieve the same subpixel size and pixel pitch with a traditional layout, separate LEDs having a size and pitch of 3 microns and 16 microns, respectively, would need to be transferred. Thus, by utilizing this “micro-monolithic” integration and layout scheme, existing transfer technology nodes may be leveraged and instantly access nodes that may double the resolution (e.g., a 7 micron node can be utilized for a 3 micron node).

The embodiments may include several advantages over typical light emitting devices and typical methods of forming light emitting devices. In particular, the embodiments may help to eliminate a back-end of line (BEOL) process entirely. The embodiments may need only one transfer step per four sub-pixels. The embodiments may provide a local cathode (e.g., substantially no voltage (IR) drop when using a common cathode ring). Further, by transferring plural sub-pixels of different pixels together, the embodiments may allow for multiple use of coupons and may also allow for low PPI displays to successfully use micro-LEDs and still maintain high utilization of the donor LED wafers.

One or more embodiments of the present disclosure may also provide for a mechanism for repairing defective micro-LEDs without needing to physically repair the light emitting device. In particular, the defective micro-LEDs may be “repaired” in the present disclosure by using a software-based approach or a hardware-based approach.

Typical light emitting devices (e.g., high-PPI display devices) may not provide a capability of repairing defective pixels without physically repairing the light emitting device. In particular, in typical light emitting devices it may only be determined that a particular micro-LED is really defective (or not) after putting down a front side electrode (e.g., a transparent electrode, such as an indium tin oxide (ITO) electrode) for the negative (e.g., n-type side) cathode contact. Even if it was possible to determine whether a micro-LED was defective before the back end of line (BEOL) process (and after transfer to backplane) by photoluminescence (PL), it would still be difficult to pull the defective micro-LED out and replace it with a good micro-LED, such as by using a pick and place (PnP) machine and local heating and soldering.

The embodiments of the present disclosure may provide an alternative that may be facilitated by the architecture of most silicon backplanes (e.g., a 2×2 configuration). In at least one embodiment, every three RGB pixels can have an extra R, G, or B redundant micro-LED. If it is determined (e.g., at the end of fabrication) that a certain micro-LED is defective, then current (or voltage) originally intended for the defective micro-LED may be turned off in software and re-directed (e.g., re-routed) to the closest micro-LED of the same color.

Thus, an approach of one or more embodiments may in effect provide a zero parts per million (ppm) light-up defectivity (e.g., a perfect panel) without physical repair, even if the original panel has, for example, up to 5000 ppm light-up defects. Typical circuitry (e.g., complementary metal oxide semiconductor (CMOS) circuitry) in the backplane may allow a signal to be changed on the fly to achieve this.

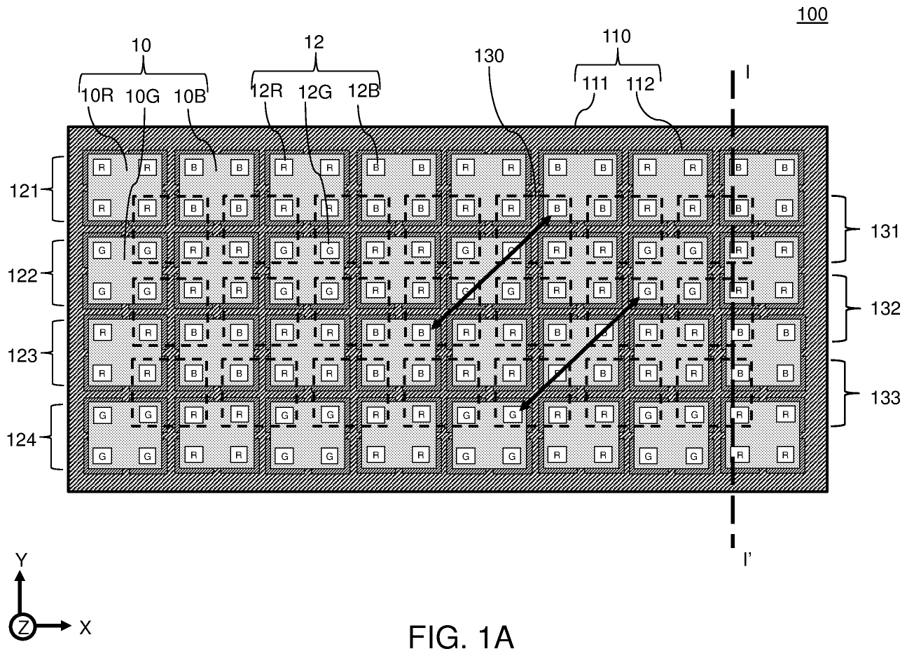

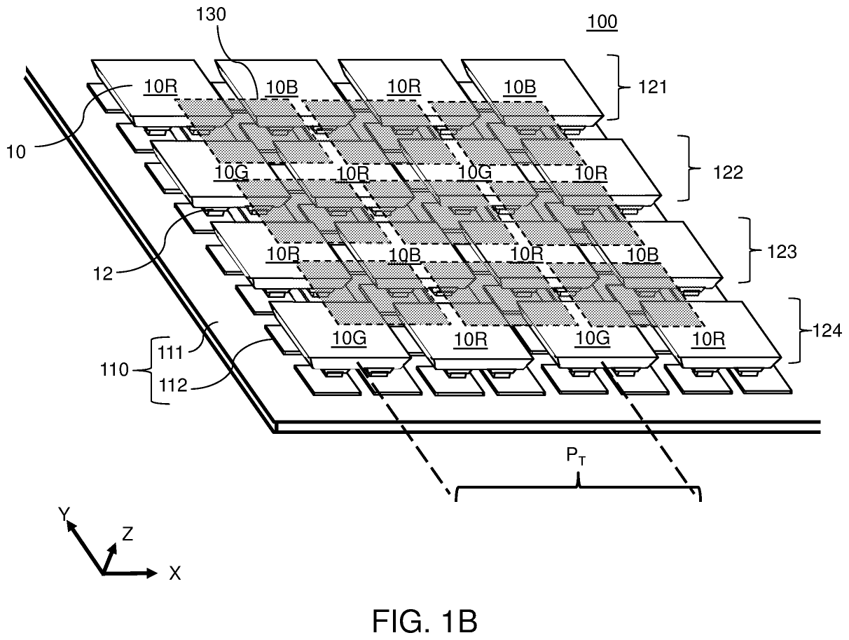

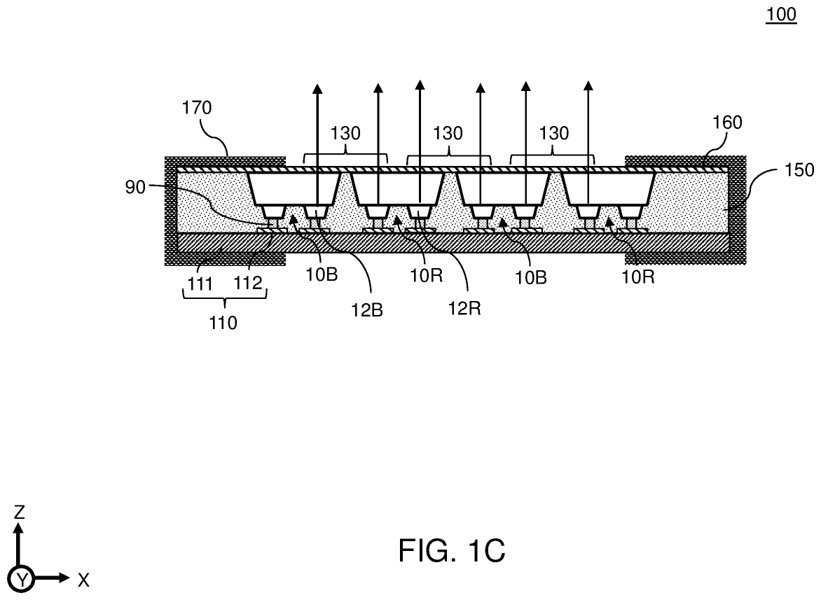

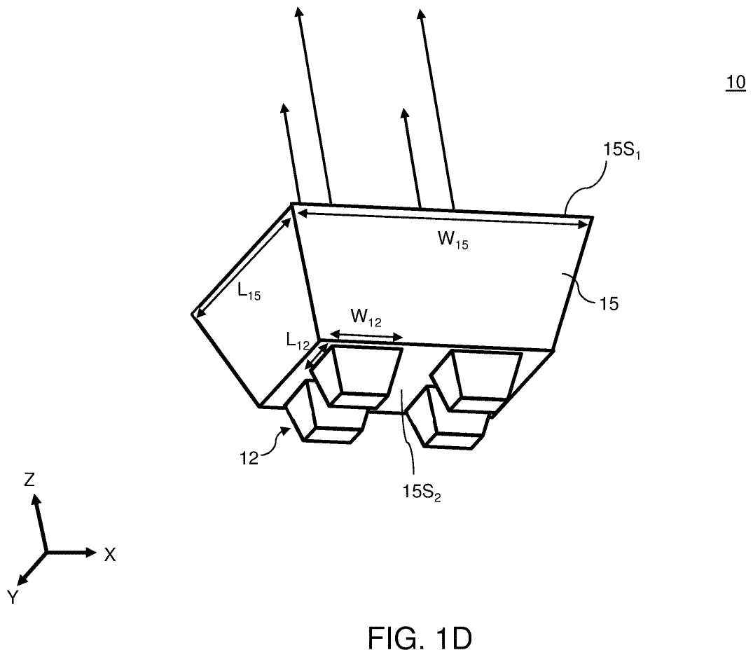

FIG. 1A is a plan view (e.g., top-down view, layout overview) of a light emitting device 100 according to one or more embodiments. FIG. 1B is a top perspective view of the lower side of the light emitting device 100 in FIG. 1A, according to one or more embodiments. It should be noted that some elements of the light emitting device 100 have been omitted in FIGS. 1A and 1B for ease of explanation. In one embodiment, the light emitting device 100 may comprise a direct view display.

As illustrated in FIG. 1A, the light emitting device 100 may include a backplane 110 including a backplane substrate 111 and bonding pads 112 formed on the substrate 111. One or more pixel driving circuits (not shown) may be formed on the backplane substrate 111 and electrically connected to the bonding pads 112. The light emitting device 100 may also include a plurality of light emitting diode (LED) dies 10 (e.g., micro-monolithic micro-LEDs) mounted on the backplane 100. The plurality of LED dies 10 may include a plurality of micro-LEDs 12. The light emitting device 100 may also include a pixel 130 including adjacent micro-LEDs 12 in adjacent LED dies 10. The pixel 130 may be driven by a pixel driving circuit on the backplane 110.

The backplane 110 may include an active matrix display backplane or a passive matrix display backplane. The backplane 110 may include a display module (not shown) for controlling the micro-LEDs 12 of the pixel 130. The display module may include, for example, complementary metal oxide semiconductor (CMOS) circuitry. The display module may include, for example, a pixel array (e.g., a two-dimensional pixel circuit arrangement) including the pixel driving circuits. The display module may also include a data driver and a scanning driver for activating the micro-LEDs 12 through the pixel driving circuits. In at least one embodiment, the display module may include control circuitry including logic elements for filling the data driver and scanning driver with data for displaying an image and a brightness of the image to be displayed. Brightness of the micro-LEDs 12 can be controlled by either using a pulse width modulation (PWM) scheme or by current modulation across the micro-LEDs 12.

As illustrated in FIG. 1A, the backplane 110 may have a rectangular shape in the plan view. However, other shapes are within the contemplated scope of disclosure. The backplane substrate 111 may include one or more layers of insulating material (e.g., dielectric material, such as a polymer material used in printed circuit boards) and/or semiconductor material (e.g., silicon, germanium, silicon germanium, etc.). The bonding pads 112 may be arranged on and/or in the backplane substrate 111 in a form of a bonding pad array (e.g., a 16×8 array is shown in FIG. 1A for ease of illustration). The bonding pad array may include, for example, one or more rows of bonding pads 112 extending in the x-direction and one or more columns of bonding pads 112 extending in the y-direction. The bonding pads 112 may have a pitch of about 8 μm or less corresponding to a sub-pixel pitch (e.g., about 8 μm) of the backplane 110. The bonding pads 112 may have a rectangular shape in the plan view. However, other shapes are within the contemplated scope of disclosure. The bonding pads 112 may include copper or another suitable metal (e.g., silver, chromium, nickel, tin, tungsten, titanium, gold, etc.), a copper alloy, or other suitable metal alloy. Other suitable metal materials are within the contemplated scope of disclosure.

The LED dies 10 may be mounted on (e.g., bonded to) the bonding pads 112 of the backplane 110. The LED dies 10 may be mounted on the backplane 110 so as to substantially overlie the bonding pads 112. In at least one embodiment, the LED dies 10 may be bonded by a solder material portion (e.g., solder bumps) to a surface of the bonding pads 112. The LED dies 10 may include, for example, one or more semiconductor material layers. In particular, the LED dies 10 may include one or more layers of Group III-V compound semiconductor material layers.

As illustrated in FIG. 1A, the LED dies 10 may be mounted on the backplane 110 in a form of an LED die array. A size and shape of the LED die array may be substantially the same as a size and shape of the bonding pad array. The LED die array may include, for example, one or more LED die rows extending in the x-direction and one or more LED die columns extending in the y-direction. The LED die rows may include a first LED die row 121, a second LED die row 122, a third LED die row 123 and a fourth LED die row 124.

The LED dies 10 may include one or more micro-LEDs 12 which may also be referred to herein as “sub-pixels” or “sub-units”. It should be noted that the micro-LEDs 12 may be on an underside of the LED dies 10 and may not be visible from a top view of the light emitting device 100 (see FIG. 1B). FIG. 1A shows a location of the micro-LEDs 12 on the underside of the LED dies 10.

As illustrated in FIG. 1A, the LED dies 10 may each include four (4) micro-LEDs 12. However, other numbers of micro-LEDs 12 may be within the contemplated scope of disclosure. The LED dies 10 may be mounted on the backplane 110 so that the micro-LEDs 12 are substantially located over the bonding pads 112, respectively. In at least one embodiment, the micro-LEDs 12 may be bonded to the bonding pads 112 by the solder material portion. The micro-LEDs 12 may be electrically connected to the pixel driving circuit through the bonding pads 112 to which the micro-LEDs 12 are bonded, respectively.

The micro-LEDs 12 may include one or more Group III-V compound semiconductor material layers. The one or more Group III-V compound semiconductor material layers may include one or more light emitting layers (e.g., active layers for emitting light). In FIG. 1A, a color of the light emitted by the light emitting layers of the micro-LEDs 12 may be indicated as either “R” for red, “G” for green or “B” for blue. A micro-LED 12 that emits light having a red color may be referred to as a red micro-LED 12R. A micro-LED 12 that emits light having a green color may be referred to as a green micro-LED 12G. A micro-LED 12 that emits light having a blue color may be referred to herein as a blue micro-LED 12B. Other colors of light or different radiation wavelengths (e.g., ultraviolet or infrared) may also be used.

In at least one embodiment, the micro-LEDs 12 on an LED die 10 may emit the same color light (i.e., light having the same peak wavelength). An LED die 10 that includes only red micro-LEDs 12R may be referred to herein as a red LED die 10R. An LED die 10 that includes only green micro-LEDs 12G may be referred to herein as a green LED die 10G. An LED die 10 that includes only blue micro-LEDs 12B may be referred to herein as a blue LED die 10B. Thus, in the light emitting device 100 in FIG. 1A, the first LED die row 121 and third LED die row 123 may include alternating red LED dies 10R and blue LED dies 10B. The second LED die row 122 and fourth LED die row 124 may include alternating green LED dies 10G and red LED dies 10R. The red LED dies 10R in adjacent rows may be staggered in the x-direction.

As further illustrated in FIG. 1A, the light emitting device 100 may include one or more pixels 130 which are indicated by dashed lines. The pixels 130 may be driven by one or more of the pixel driving circuits in the backplane 110. The pixels 130 may include adjacent micro-LEDs 12 from adjacent LED dies 10. In at least one embodiment, the pixels 130 may include two red micro-LEDs 12R, a green micro-LED 12G and a blue micro-LED 12B. In that case, the pixels 130 may be referred to as RRGB pixels 130. Alternatively, each pixel 130 may include two green micro-LEDs 12G or two blue micro-LEDs 12B. The pixels 130 may be arranged on the backplane 110 in the form of a pixel array. The pixel array may include, for example, one or more pixel rows extending in the x-direction. The pixel rows may include a first pixel row 131, a second pixel row 132, and a third pixel row 133. The pixel array may also include one or more columns of the pixels 130 extending in the y-direction.

In at least one embodiment, the pixels 130 in the first pixel row 131 may include adjacent micro-LEDs 12 from adjacent LED dies 10 in the first LED die row 121 and the second LED die row 122. In particular, the pixels 130 in the first pixel row 131 may include a red micro-LED 12R from a red LED die 10R in the first LED die row 121, a blue micro-LED 12B from a blue LED die 10B in the first LED die row 121, a green micro-LED 12G from a green LED die 10G in the second LED die row 122, and a red micro-LED 12R from a red LED die 10R in the second LED die row 122.

The pixels 130 in the second pixel row 132 may include adjacent micro-LEDs 12 from adjacent LED dies 10 in the second LED die row 122 and the third LED die row 123. In particular, the pixels 130 in the second pixel row 132 may include a red micro-LED 12R from a red LED die 10R in the second LED die row 122, a green micro-LED 12G from a green LED die 10G in the second LED die row 122, a blue micro-LED 12B from a blue LED die 10B in the third LED die row 123, and a red micro-LED 12R from a red LED die 10R in the third LED die row 123.

The pixels 130 in the third pixel row 133 may include adjacent micro-LEDs 12 from adjacent LED dies 10 in the third LED die row 123 and the fourth LED die row 124. The pixels 130 in the third pixel row 133 may have a configuration similar to the configuration of the pixels 130 in the first pixel row 131. In particular, the pixels 130 in the third pixel row 133 may include a red micro-LED 12R from a red LED die 10R in the third LED die row 123, a blue micro-LED 12B from a blue LED die 10B in the third LED die row 123, a green micro-LED 12G from a green LED die 10G in the fourth LED die row 124, and a red micro-LED 12R from a red LED die 10R in the fourth LED die row 124.

Thus, each LED die 10 includes plural micro-LEDs 12 located in different adjacent pixels. For example, each LED die 10 may include four micro-LEDs 12 which emit the same color light (i.e., emit radiation with the same peak wavelength) and which are located in four different pixels 130.

In at least one embodiment, a size of the red LED dies 10, green LED dies 10 and blue LED dies 10B may be about 7 μm or less, and a size of the micro-LEDs 12 on the LED dies 10 may be about 3 μm or less. A pitch between the LED dies may be about 16 μm or less, and a transferred pitch (PT) between like LED dies (e.g., a pitch between green LED dies 10G; see FIG. 1B) may be about 32 μm or less. The size of the LED dies 10 and pitch (e.g., 16 μm or less) between LED dies 10 in the light emitting device 100 may provide a large diagonal distance between the blue micro-LEDs 12B and a large diagonal distance between the green micro-LEDs 12G (as indicated by the arrows in FIG. 1A).

The size and pitch of the LED dies 10 may also help to alleviate the problems associated with fabricating typical light emitting devices that may require transferring small (e.g., 5 μm or less) devices. In at least one embodiment, the transferred device size (e.g., about 7 μm or less), and the transferred pitch PT (e.g., about 32 μm or less) may achieve a subpixel size (e.g., a size of the micro-LED 12) of about 3 μm and pixel pitch of about 16 μm. To achieve the same subpixel size and pixel pitch with a typical layout, devices at a size and pitch of 3 μm and 16 μm, respectively, would need to be transferred. Thus, in essence, by utilizing the “micro-monolithic” integration and layout scheme of the embodiments of the present disclosure, existing transfer technology nodes (e.g., in the backplane 110) may be leveraged and instantly accessed (e.g., a 7 μm node can be utilized for a next-gen 3 μm node) so that a resolution of the light emitting device 100 may be twice a resolution of a typical light emitting device.

It should be noted that several aspects of the embodiments may be readily varied or altered. In particular, a variation or alteration of the number of micro-LEDs 12 on the LED die 10, a size and pitch of the LED dies 10, a size and pitch of the micro-LEDs 12, a size and pitch of the pixels, a shape of the LED die array (e.g., layout lattice) (e.g., square lattice, triangular lattice, hexagonal lattice), a location of colors with the LED die array, and aspects of the micro-LED wafer-level integration (metallization, mesa profiles, LED shaping, etc.) may be within the contemplated scope of disclosure. In particular, it should be noted that the RRGB pixels 130 in the light emitting device 100 in FIG. 1A may instead be configured as GGRB pixels by replacing the red LED dies 10R in FIG. 1A with green LED dies 10G and replacing the green LED dies 10G in FIG. 1A with red LED dies 10R. Furthermore, each LED die 10 may include more or less than four subpixels 12. For example, each LED die 10 may include two, three, five or six subpixels which are located in two, three, five or six different pixels 130.

FIG. 1C is a vertical cross-sectional view of the light emitting device 100 along the line I-I′ in FIG. 1A, according to one or more embodiments. In particular, FIG. 1C is a view along a column of the LED die array that includes red LED dies 10R and blue LED dies 10B.

As illustrated in FIG. 1C, the LED dies 10 (e.g., red LED dies 10R and blue LED dies 10B) may be flip chip mounted to the respective bonding pads 112 of the backplane 110. Each micro-LED 12 may be mounted to a separate bonding pad 112 which may be driven separately by the backplane 110. A solder material portion 90 may be formed between the micro-LEDs 12 and the bonding pads 112. The solder material portion 90 may include, for example, a tin-silver-copper alloy including about 3-4% silver, 0.5-0.7% copper, and the balance (95%+) tin. A fourth metal such as indium, antimony, bismuth, zinc, or manganese may be added to the tin-silver-copper alloy.

In at least one embodiment, a p-type layer (not shown) of the micro-LEDs 12 may be electrically connected to the bonding pads 112. In other words, in one embodiment, each micro-LED is bonded p-side down to the backplane 110 and has a common n-side with the other micro-LEDs 12 (e.g., with three other micro-LEDs 12) in the same LED die 10. Thus, the bonding pads 112 may serve as an anode in the light emitting device 100. The light emitting device 100 may include one or more dielectric material layers 150 formed between the LED dies 10 so as to substantially surround (in the x-y direction) the LED dies 10. The LED dies 10 may be substantially embedded in the dielectric material layer 150. An upper surface of the dielectric material layer 150 may be substantially coplanar with an upper surface of the LED dies 10. The dielectric material may include, for example, a polymer material, silicon oxide or aluminum oxide. However, other dielectric materials may be within the contemplated scope of disclosure.

The light emitting device 100 may further include a continuous n-type (i.e., n-type side) contact layer 160 (e.g., first conductivity type contact layer) formed on the upper surface of a plurality of the LED dies 10 and the upper surface of the dielectric material layer 150. The n-type contact layer 160 may be electrically connected to an n-type layer of the micro-LEDs 12 and, therefore, may serve as a shared cathode for plural LED die 10 in the light emitting device 100. The n-type contact layer 160 may include an optically transparent material. In at least one embodiment, the n-type contact layer 160 may include indium tin oxide (ITO) or another transparent, conductive metal oxide. A light emitted by the micro-LEDs 12 may be directed through the n-type contact layer 160 in an area of the pixels 130, as indicated by the arrows extending in the z-direction in FIG. 1C. Thus, an upper surface of the n-type contact layer 160 may serve as a light emitting surface of the light emitting device 100.

The light emitting device 100 may also include a frame 170. The frame 170 may be formed around an outer periphery of the light emitting device 100 (e.g., an outer periphery of the backplane 110, the dielectric material layer 150 and the n-type contact layer 160). In particular, the frame 170 may wrap continuously around the periphery of the light emitting device 100 (e.g., from a front side to a back side). The frame 170 may include one or more metal or plastic materials. However, other materials may be within the contemplated scope of disclosure.

In operation, a voltage or current may be applied across one of the micro-LEDs 12 (e.g., a selected micro-LED 12) in the LED die 10 while the other micro-LEDs 12 (e.g., unselected micro-LEDs 12) in the same LED die 10 may be electrically inactive. This may be accomplished by applying a voltage or current to the bonding pad 112 bonded to the selected micro-LED 12 relative to the n-type contact layer 160, while no voltage or current is applied to the bonding pads 112 bonded to the unselected micro-LEDs 12 of the same LED die 10. This causes the selected micro-LED 12 (i.e., subpixel) in one pixel 130 to emit light while the unselected micro-LEDs 12 of the same LED die 10 which are subpixels located in other pixels do not emit light.

FIG. 1D is a bottom perspective view of the LED die 10 according to one or more embodiments. As illustrated in FIG. 1D, the LED die 10 may include an LED die base layer 15 (e.g., a strap layer) and one or more micro-LEDs 12 formed on the LED die base layer 15. The LED die base layer 15 may have a shape of a trapezoidal prism. However, other shapes are within the contemplated scope of disclosure. The LED die base layer 15 may have a first surface 15S₁ and a second surface 15S₂ opposite the first surface 15S₁. The first surface 15S₁ may include a light emitting surface as indicated by the unidirectional arrows in FIG. 1D. An area of the first surface 15S₁ may be greater than an area of the second surface 15S₂. At the first surface 15S₁, the LED die base layer 15 may have a width W₁₅ in the x-direction and a length L₁₅ in the y-direction. In at least one embodiment, the width W₁₅ may be substantially equal to the length L₁₅. The width W₁₅ and/or length L₁₅ may be 20 μm or less, such as 7 to 10 μm.

The LED die base layer 15 may include one or more layers of n-type semiconductor material. In at least one embodiment, the n-type semiconductor layer may include a n-type Group III-V compound semiconductor material layer. such as n-type GaN. A light emitted by the micro-LEDs 12 may be directed through the LED die base layer 15 as indicated by the unidirectional arrows. Thus, the first surface 15S₁ of the LED die base layer 15 may serve as a light emitting surface of the LED die 10.

As further illustrated in FIG. 1D, the micro-LEDs 12 may be formed on the second surface 15S₂ of the LED die base layer 15. In particular, the micro-LEDS 12 may be formed as discrete mesas on the second surface 15S₂. The micro-LEDs 12 (e.g., mesas) may have a tapered shape that is substantially similar to the tapered shape of the LED die base layer 15. In particular, the micro-LEDs 12 may also have the shape of a trapezoidal prism.

However, other shapes are within the contemplated scope of disclosure. At the second surface 15S₂, the micro-LEDs 12 may have a width W₁₂ in the x-direction and a length L₁₂ in the y-direction. In at least one embodiment, the width W₁₂ may be substantially equal to the length L₁₂. The width W₁₂ and/or length L₁₂ may be about 3 μm or less, such as 500 nm to 3 μm.

The micro-LEDs 12 may include, for example, a light emitting layer (e.g., an active layer; not shown) and other layers (not shown) on the light emitting layer. The light emitting layer may have a quantum well (QW) or multiple quantum well (MQW) configuration. In at least one embodiment, the light emitting layer may include indium gallium nitride (InGaN), which has a narrower band gap than GaN, which allows the light emitted from the InGaN to pass through the n-type GaN base layer 115. The contact portion may include a p-type semiconductor material (e.g., second conductivity type semiconductor material). In at least one embodiment, the contact portion may include a p-type Group III-V compound semiconductor material layer such as p-type GaN. The other layers may also include a reflective layer (not shown) for reflecting light from the light emitting layer back toward the first surface 15S₁ of the LED die base layer 15. The reflective layer may include a metal such as aluminum, silver, etc.

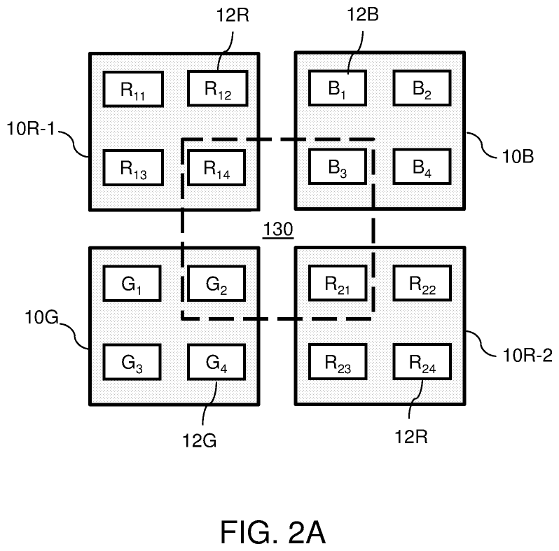

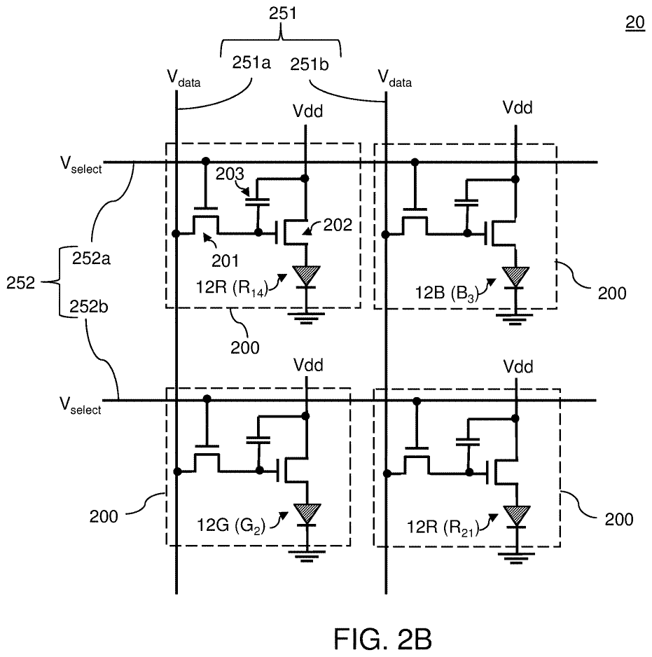

FIG. 2A is a schematic diagram of a pixel 130 that may include a portion of four adjacent LED dies 10 in the light emitting device 100 according to one or more embodiments. As illustrated in FIG. 2A, the four adjacent LED dies 10 may include a first red LED die 10R-1 including four red micro-LEDs 12R which may be referred to as R₁₁, R₁₂, R₁₃ and R₁₄, a blue LED die 10B including four blue micro-LEDs 12B which may be referred to as B₁, B₂, B₃ and B₄, a green LED die 10G including four green micro-LEDs 12G which may be referred to as G₁, G₂, G₃ and G₄, and a second red LED die 10R-2 including four red micro-LEDs 12R which may be referred to as R₂₁, R₂₂, R₂₃ and R₂₄. The pixel 130 may be formed of the four adjacent micro-LEDs 12R in the adjacent LED dies 10. In particular, the pixel 130 may be formed of the red micro-LED R₁₄, blue micro-LED B₃, green micro-LED G₂ and red micro-LED R₂₁.

FIG. 2B is a schematic diagram of a portion of a pixel array 20 that may be included in the display module of the backplane 110 according to one or more embodiments. As illustrated in FIG. 2B, the pixel array 20 may include an active matrix pixel array. However, pixel array 20 may alternatively include a passive matrix pixel array. The pixel array 20 may include data lines 251 (251a, 251b) and select lines 252 (252a, 252b). A pixel driving circuit 200 may be located at an intersection of a data line 251 and select line 252. The pixel driving circuits 200 may include micro-LEDs 12, respectively. As illustrated in FIG. 2B, a pixel driving circuit 200 for the red micro-LED 12R (R₁₄) may be connected to data line 251a and select line 252a. A pixel driving circuit 200 for the green micro-LED 12G (G₂) may be connected to data line 251a and select line 252b. A pixel driving circuit 200 for the blue micro-LED 12B (B₃) may be connected to data line 251b and select line 252a. A pixel driving circuit 200 for the red micro-LED 12R (R₂₁) may be connected to data line 251b and select line 252b. Thus, an operation of the pixel 130 in FIG. 2A may be controlled at least in part through the four pixel driving circuits 200 in FIG. 2B.

As illustrated in FIG. 2B, the pixel driving circuit 200 (e.g., pixel circuit) may have a 2-Transistor, 1-Capacitor (2T1C) configuration located on the backplane 110. However, other configurations of the pixel driving circuit 200 may be within the contemplated scope of disclosure. The pixel driving circuit 200 may include a first transistor 201 (e.g., switching transistor), a second transistor 202 (e.g., driving transistor) and a capacitor 203 (e.g., storage capacitor). The first transistor 201 and second transistor 202 may include thin film transistors (TFTs).

The first transistor 201 (e.g., first TFT) may be connected to a data line 251 in the pixel array 20 of the backplane 110. A control gate of the first transistor 201 may be connected to a select line 252 in the pixel array 20. The second transistor 202 (e.g., second TFT) may be connected between a power supply Vdd and the micro-LED 12. A control gate of the second transistor 202 may be connected to the data line 251 through the first transistor 201. The capacitor 203 may be connected between the power supply Vdd and the control gate of the second transistor 202. The first transistor 201 (e.g., switching TFT) may, therefore, serve as a pass gate for passing data on the data line 251 to the storage capacitor 203 and turning on the second transistor 202 (e.g., driving TFT) when a select signal is transmitted on the select line 252. When the second transistor 202 is turned on, micro-LED 12 may be activated and emit light from its light emitting layer.

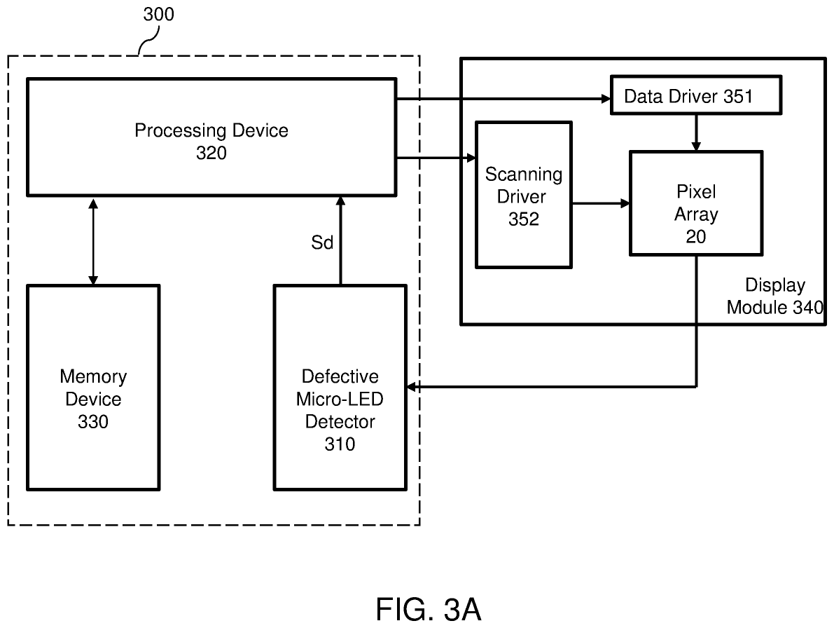

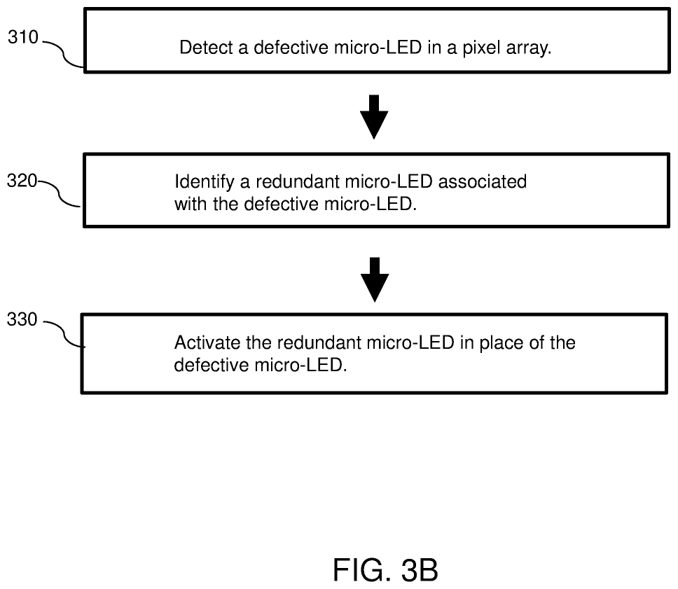

FIG. 3A is a schematic diagram of a defect repair system 300 for repairing a defective micro-LED 12 in the light emitting device 100 according to one or more embodiments. The defect repair system 300 may be used to implement a software-based approach to repairing a defective micro-LED 12. However, a hardware-based approach may alternatively be used to repair a defective micro-LED 12. At least a portion of the defect repair system 300 may be connected to or included within the backplane 110. The light emitting device 100 may be designed to substantially eliminate defective micro-LEDs 12. That is, the light emitting device 100 may provide zero light-up parts per million (PPM) defectivity without requiring physical repair.

The software-based approach that may be facilitated by the architecture of most silicon backplanes (e.g., a 2×2 configuration). Generally, if it is determined that a micro-LED 12 is defective, then current to the defective micro-LED 12 may be turned off using software. The current may then be routed to a micro-LED 12 of the same color that is near (e.g., closest to) the defective micro-LED 12. In at least one embodiment, the current may be routed to the redundant micro-LED in the pixel 130 having the defective micro-LED 12. In this manner, one or more embodiments may provide a zero PPM light-up defectivity (e.g., a perfect panel) even if the original light emitting device 100 has up to 5000 ppm light-up. In at least one embodiment, the current may be routed to a redundant micro-LED that is outside the pixel 130 having the defective micro-LED 12.

In at least one embodiment, the defect repair system 300 may be included as part of a control system for the light emitting device 100. The defect repair system 300 may include, for example, a defective micro-LED detector 310, a processing device 320 and a memory device 330. The defective micro-LED detector 310 may be connected to the pixel array 20 that is included in a display module 340 of the light emitting device 100. The defective micro-LED detector 310 may detect a defective micro-LED 12 in the pixel array 20. The defective micro-LED detector 310 may include, for example, a sensing circuit that senses a voltage or current on a power supply line that supplies power (Vdd) to the micro-LED 12. If the defective micro-LED detector 310 senses a voltage or current on the power supply line that is different than expected, then the defective micro-LED detector 310 may transmit a defect notification signal Sd to the processing device 320. The defect notification signal Sd may include an identity and/or location of the defective micro-LED 12 in the pixel array 20.

The memory device 330 may include, for example, read-only memory (ROM) and/or random access memory (RAM). The memory device 330 may be physically located in a location that is remote from the processing device 320. The memory device 330 may store a defect repair program including instructions for repairing the defective micro-LED in the pixel array 20. The processing device 320 may include a central processing device (CPU), microcontroller, microprocessor, etc. Upon receiving the defect notification signal Sd, the processing device 320 may access the memory device 330 and execute the instructions in the defect repair program stored in the memory device 330. The defect repair program may include, for example, a lookup table that indicates a redundant and/or adjacent micro-LED 12 associated with the defective micro-LED 12.

The display module 340 may include a data driver 351 for driving the data lines 251 (see FIG. 2B) with data in the pixel array 20. The display module 340 may also include a scanning driver 352 for driving the select lines 252 (see FIG. 2B) with a select signal in the pixel array 20. After executing the instructions, the processing device 320 may control the data driver 351 to re-route the data on the data lines 251 from the defective micro-LED 12 to the redundant micro-LED 12. The processing device 320 may also control the scanning driver 351 to re-route the select signal on the select lines 252 from the defective micro-LED 12 to the redundant micro-LED 12.

Thus, for example, referring to the pixel 130 in FIG. 2B, the red micro-LED 12R (R₁₄) may be activated by transmitting data on the data line 251a and a transmitting a select signal on select line 252a. The red micro-LED 12R (R₂₁) (e.g., the redundant red micro-LED 12 in the pixel 130) may be activated by transmitting data on the data line 251b and a transmitting a select signal on select line 252b. If the defective micro-LED detector 310 detects that the red micro-LED 12R (R₁₄) is defective, then the defective micro-LED detector 310 may notify the processing device 320. The processing device 320 may execute the instructions of the defect repair program stored in the memory device 330. The processing device 320 may then operate pursuant to the executed instructions to control the data driver 351 and scanning driver 352 to activate the redundant red micro-LED 12R (R₂₁) instead of the red micro-LED 12R (R₁₄). That is, under the control of the processing device 320, instead of the data driver 351 transmitting data on data line 251a and the scanning driver 352 transmitting a select signal on select line 252a, the data driver 351 may transmit data on data line 251b and the scanning driver 352 may transmit a select signal on select line 252b.

The processing device 320 may also store repair data in the memory device 330 so that the redundant red micro-LED 12R (R₂₁) may permanently replace red micro-LED 12R (R₁₄) in the pixel 130. Thus, the data driver 351 and scanning driver 352 may continue to activate the redundant red micro-LED 12R (R₂₁) in place of the red micro-LED 12R (R₁₄) in the pixel 130 indefinitely.

FIG. 3B is a flow chart illustrating a method of repairing a defective micro-LED 12 according to one or more embodiments. The method may be performed, for example, using the defect repair system 300. Step 310 includes detecting a defective micro-LED 12 in a pixel array. Step 320 includes identifying a redundant micro-LED 12 associated with the defective micro-LED 12. Step 330 includes activating the redundant micro-LED 12 in place of the defective micro-LED 12.

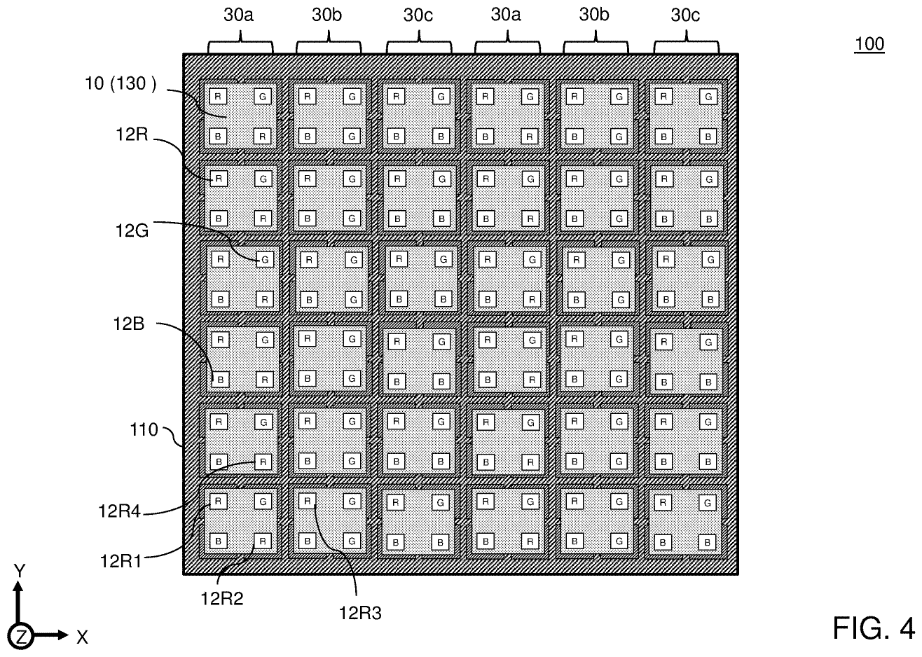

FIG. 4 is a schematic diagram of the light emitting device 100 having an alternative layout pattern for the LED dies 10 according to one or more embodiments. In the alternative layout pattern of FIG. 4, the LED dies 10 may be referred to collectively as “RGB LED dies 10” because each of the LED dies 10 may include at least one red micro-LED 12R, at least one green micro-LED 12G and at least one blue micro-LED 12B. The RGB LED dies 10 may also include one redundant micro-LED 12. In particular, some of the RGB LED dies 10 may include a redundant red micro-LED 12R and may therefore be referred to as RRGB LED dies 10. Some of the RGB LED dies 10 may include a redundant green micro-LED 12G and may therefore be referred to as RGGB LED dies 10. Some of the RGB LED dies 10 may include a redundant blue micro-LED 12B and may therefore be referred to as RGBB LED dies 10.

In the alternative layout pattern of FIG. 4, the light emitting device 100 may include a first LED die column 30a including RRGB LED dies 10, a second LED die column 30b including RGGB LED dies 10 and a third LED die column 30c including RGBB LED dies 10. The pattern of first LED die column 30a, second LED die column 30b and third LED die column 30c may be repeated one time to form a 12×12 array of LED dies 10. The LED dies 10 may also constitute pixels 130 in the light emitting device 100. Thus, the light emitting device 100 may include at least a 12×12 array of pixels 130 (e.g., 144 pixels).

Thus, in the alternative layout pattern, every third RGB LED die 10 (e.g., RGB pixel 130) can have an extra R, G, and B redundant micro-LED 12. That is, the pixels 130 in the first LED die column 30a may include a redundant red micro-LED 12R, the pixels 130 in the second LED die column 30b may include a redundant green micro-LED 12G and the pixels 130 in the third LED die column 30c may include a redundant blue micro-LED 12B.

The alternative layout pattern may be implemented with the defect repair system 300 (see FIG. 3A) to efficiently and effectively repair defective micro-LEDs 12 in the light emitting device 100. For example, if it is determined that red micro-LED 12R1 in LED die column 30a is defective, then the defect repair system 300 may cause the redundant red micro-LED 12R2 in the same pixel 130 to be activated in place of the defective red micro-LED 12R1. However, the LED dies 10 (e.g., pixels 130) in LED die column 30b do not include a redundant red micro-LED 12R. Therefore, if it is determined that red micro-LED 12R3 in LED die column 30b is defective, then defect repair system 300 may identify a redundant red micro-LED 12R outside of LED die column 30b. For example, the defect repair system 300 may identify the red micro-LED 12R2 or the red micro-LED 12R4 as the redundant red micro-LED 12R.

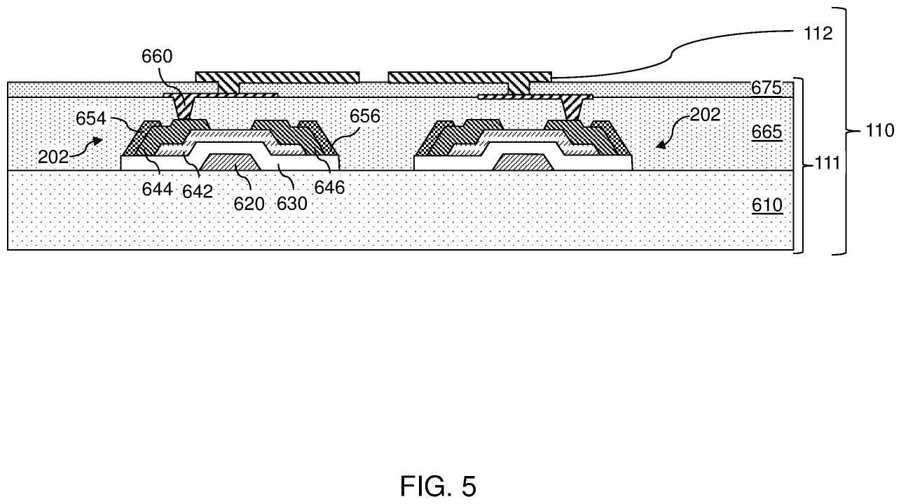

FIG. 5 is a vertical cross-sectional view of the backplane 110, according to one or more embodiments. The backplane 110 may include a backplane lower substrate 610. The backplane lower substrate 610 may include, for example, an insulating material (e.g., dielectric material) and/or semiconductor material (e.g., silicon, germanium, silicon germanium, etc.). Control circuitry for controlling an operation of the light emitting device 100 may be formed on the backplane lower substrate 610. Such control circuitry may include, for example, the display module 340 (e.g., see FIG. 3A) and in particular, the pixel array 20 of the display module 340. As illustrated in FIG. 5, the second transistor 202 (e.g., driving transistor; second TFT) of the pixel driving circuit 200 may be formed on the backplane lower substrate 610. The second transistors 202 may be formed on the backplane lower substrate 610 in a 16×8 array configuration, so as to accommodate the later formation of the 16×8 array configuration of bonding pads 112 (e.g., see FIG. 1A). It should be noted that there may be more than 16×8 bonding pads in the display device.

The second transistor 202 may include a gate electrode 620, a gate dielectric 630, a channel region 642, a source region 646, and a drain region 644. While the second transistor 202 is depicted in FIG. 5 as an inverted staggered TFT, other types of TFTs, such as inverted coplanar, top gated staggered and top gated coplanar TFTs can be used instead. Source interconnect wiring 656 and drain interconnect wiring 654 may also be formed on the second transistor 202. The backplane 110 may include other interconnect wiring to connect the second transistors 202 to electrical interfaces on the backplane lower substrate 610. An encapsulation dielectric layer 665 may be formed on backplane lower substrate 610 and may encapsulate the second transistors 202. First-level metal interconnect structures 660 may be formed through the encapsulation dielectric layer 4665 to a node of the second transistor 202 such as a drain region 644 (or source region 646).

An interconnect level dielectric layer 675 may be formed over the encapsulation dielectric layer 665. The backplane lower substrate 610, encapsulation dielectric layer 665 and interconnect level dielectric layer 675 may together constitute the backplane substrate 111. As illustrated in FIG. 5, the bonding pads 112 (e.g., second-level metal interconnect structures) may be formed on the interconnect level dielectric layer 675 of the backplane substrate 111. The bonding pads 112 may be connected to the first-level metal interconnect structures 660 through an opening in the interconnect level dielectric layer 675.

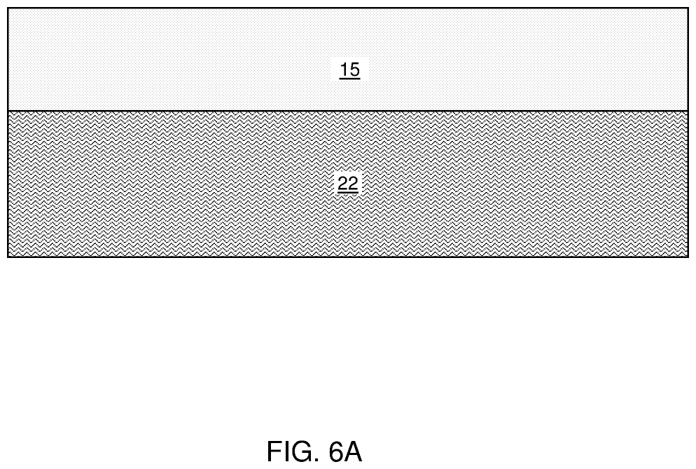

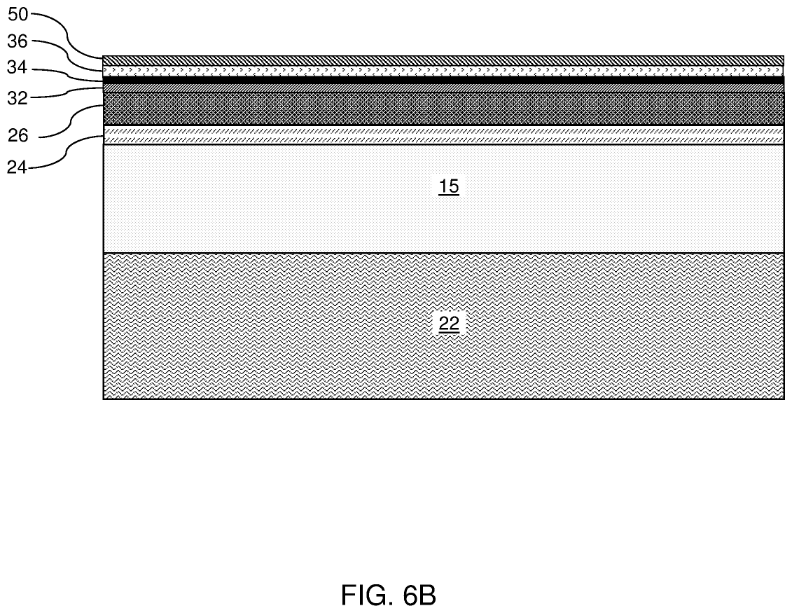

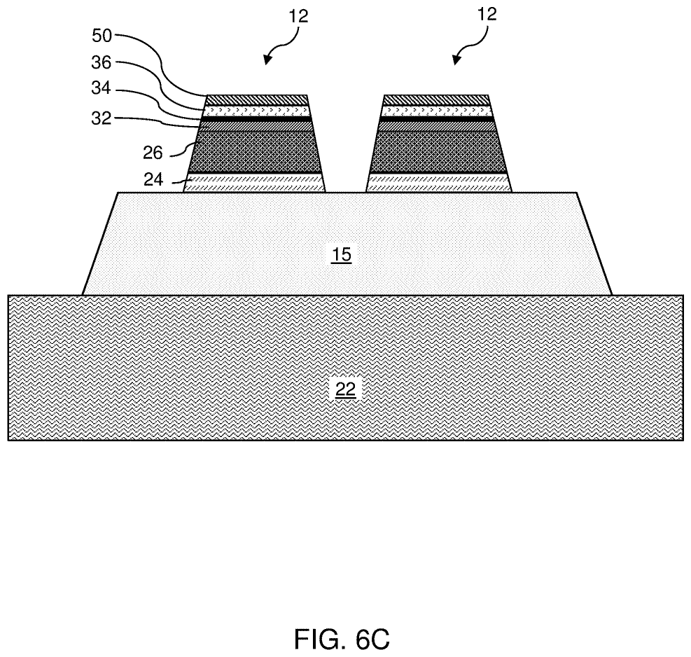

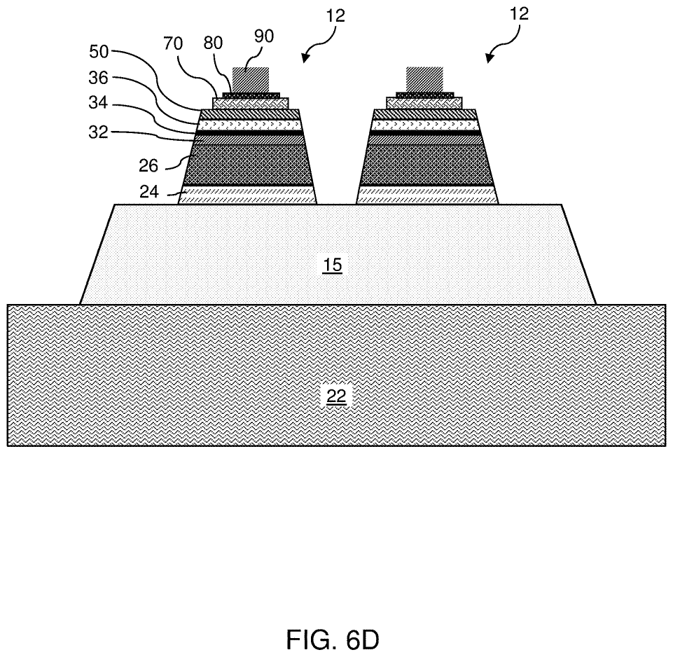

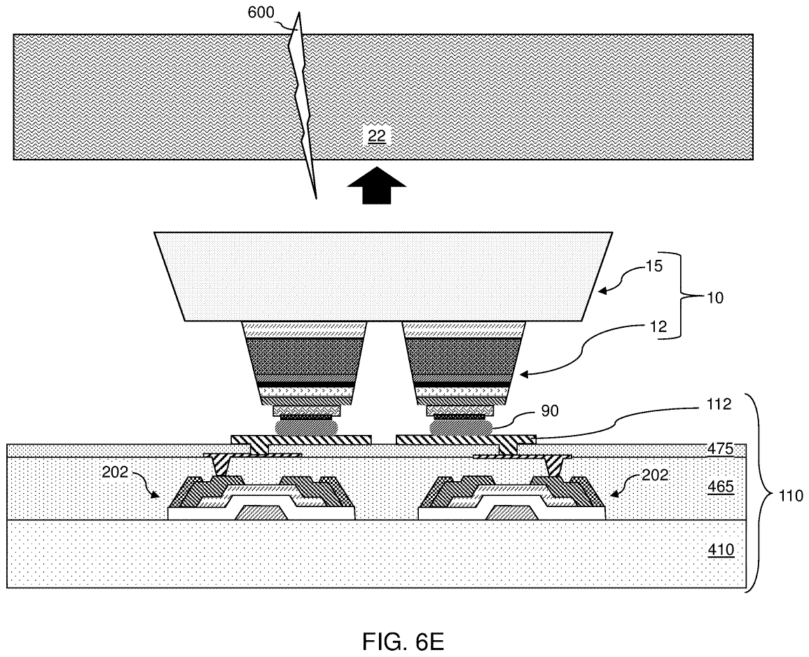

FIGS. 6A-6E illustrate a method of forming an LED die 10 (e.g., micro-monolithic micro-LED) according to one or more embodiments. In particular, the method illustrated in FIGS. 6A-6E may be used to form the LED die 10 in the light emitting device 100 of FIG. 1A. That is, the LED die 10 in FIGS. 6A-6E may include a red LED die 10R, a green LED die 10G or a blue LED die 10B.

FIG. 6A is a vertical cross-sectional view of an exemplary intermediate structure including an LED die base layer 15 formed on a substrate 22, according to one or more embodiments. The substrate 22 may be referred to as a growth substrate. The substrate 22 may include a single crystalline growth substrate material such as Al₂O₃ (sapphire) using either basal plane or r-plane growing surfaces, diamond, Si, Ge, GaN, AlN, SiC in both wurtzite (a) and zincblende (B) forms, InN, GaP, GaAsP, GaAs, InP, ZnO, ZnS, and ZnSe. For example, the substrate 22 may include sapphire (i.e., single crystalline aluminum oxide) with a suitable surface orientation. The substrate 22 may include a patterned sapphire substrate (PSS) having a patterned (e.g., rough) growth surface. Bumps, dimples, and/or angled cuts may, or may not, be provided on the top surface of the substrate 22 to facilitate epitaxial growth of an upper layer on the substrate 22, and/or to facilitate separation of an upper layer from the substrate 22 in a subsequent separation process.

The LED die base layer 15 may include one or more layers of semiconductor material grown on the substrate 22. The semiconductor material may include, for example, a Group III-V compound semiconductor material. In particular, the semiconductor material may include a Group III nitride compound semiconductor material such as n-type GaN. The LED die base layer 15 may be formed by any suitable method such as metalorganic vapor phase epitaxy (MOVPE), molecular beam epitaxy (MBE), hydride vapor phase epitaxy (HVPE), liquid phase epitaxy (LPE), metal-organic molecular beam epitaxy (MOMBE), and atomic layer deposition (ALD).

FIG. 6B is a vertical cross-sectional view of an exemplary intermediate structure including various layers of a micro-LED 12 on the LED die base layer 15, according to one or more embodiments. A single crystalline buffer semiconductor layer 24 may be formed on the LED die base layer 15 by a suitable method including, for example, MOVPE, MBE, HVPE, LPE, MOMBE, and ALD. The single crystalline compound semiconductor material 24 may include, for example, a Group III-V compound semiconductor material, and in particular, a Group III-nitride compound semiconductor material. In at least one embodiment, the single crystalline buffer semiconductor layer 24 may include one or more of gallium nitride (GaN), aluminum nitride (AIN), indium nitride (InN), gallium aluminum nitride, and gallium indium nitride, as well as other III-V materials, such as gallium phosphide (GaP), gallium arsenide (GaAs), gallium antimonide (GaSb), Indium phosphide (InP), indium arsenide (InAs), and indium antimonide (InSb).

An n-doped compound semiconductor substrate layer 26 may be formed on the single crystalline buffer semiconductor layer 24. The n-doped compound semiconductor substrate layer 26 may be formed as a continuous material layer having a uniform thickness over the entire top surface of the single crystalline buffer semiconductor layer 24. The n-doped compound semiconductor substrate layer 26 may be lattice matched with the single crystalline compound semiconductor material of the top portion of the single crystalline buffer semiconductor layer 24. The n-doped compound semiconductor substrate layer 26 may, or may not, include the same compound semiconductor material as the top portion of the single crystalline buffer semiconductor layer 24. In at least one embodiment, the n-doped compound semiconductor substrate layer 26 can include an n-doped direct band gap compound semiconductor material. In at least one embodiment, the n-doped compound semiconductor substrate layer 26 can include n-doped gallium nitride (GaN), indium gallium nitride (InGaN) or other III-V compound semiconductor materials, such as gallium phosphide or its ternary or quaternary compounds. The n-doped compound semiconductor substrate layer 26 may be formed by any suitable method including, for example, MOVPE, MBE, HVPE, LPE, MOMBE, and ALD.

An n-doped compound semiconductor region 32 may be grown on the n-doped compound semiconductor substrate layer 26. An optional patterned growth mask layer (not shown) may be formed the n-doped compound semiconductor substrate layer 26, in which case the n-doped compound semiconductor region 32 may be grown through openings in the patterned growth mask layer. The n-doped compound semiconductor region 32 may be grown, for example, by a selective compound semiconductor deposition process which may include a selective epitaxy process. If the optional patterned growth mask layer is present, then the shapes and sizes of the n-doped compound semiconductor region 32 may be determined based on the shapes and dimensions of the openings through the patterned growth mask layer and by the process conditions of the selective compound semiconductor deposition process. The n-doped compound semiconductor region 32 may be formed with various crystallographic facets located within a respective crystallographic plane. The n-doped compound semiconductor region 32 may include a microdisc, nanodisc, nanowire cores, microwire cores, nanopyramids, micropyramids, nanofrustums, microfrustums, combinations thereof, or other nanoscale structures or microscale structures. Alternatively, the n-doped compound semiconductor region 32 may comprise a continuous planar semiconductor layer.

An active region 34 may be formed (e.g., by selective epitaxy process) on the n-doped compound semiconductor region 32. The active region 34 may include an optically active compound semiconductor layer stack configured to emit light. The active region 34 may include one or more layers (e.g., active layers) of semiconductor material that emit light upon application of a suitable electrical bias. The active region 34 may include one or more layers of Group III-V compound semiconductor material such as gallium nitride, indium gallium nitride well, aluminum gallium nitride, etc. The active region 34 may include any other suitable semiconductor layer (e.g., such as gallium phosphide or its ternary or quaternary compounds) or stack of layers for light emitting diode applications provided that it can be grown on the n-doped compound semiconductor region 32. The active region 34 may include a quantum well (QW) or a multi-quantum well (MQW) structure that emits light upon application of an electrical bias thereacross. For example, the active region 34 may include indium gallium nitride well(s) located between gallium nitride or aluminum gallium nitride barrier layers.

A p-doped semiconductor material layer 36 may be formed (e.g., by selective deposition such as selective epitaxy) on the active region 34 (e.g., on the planar top surfaces and, if present, on the faceted outer surfaces of the active region 34). The p-doped semiconductor material layer 36 may include a doped semiconductor material having a doping of a second conductivity type, which is the opposite of the first conductivity type. The p-doped semiconductor material layer 36 can include a compound semiconductor material. The compound semiconductor material of the p-doped semiconductor material layer 36 can be any suitable semiconductor material, such as p-type Group III-nitride compound semiconductor material, e.g., gallium nitride and/or aluminum gallium nitride. In one embodiment, the n-doped compound semiconductor region 32 can include n-doped GaN or InGaN, and the p-doped semiconductor material layer 36 can include p-doped AlGaN and/or GaN. The n-doped compound semiconductor region 32 and/or the p-doped semiconductor material layer 36 can include other semiconductor materials, such as such as gallium phosphide or its ternary or quaternary compounds.

An anode contact layer 50 may be formed on the p-doped semiconductor material layer 36. The anode contact layer 50 may include one or more layers (e.g., a layer stack) including one or more of a nickel layer, a platinum layer, a silver layer and/or a transparent conductive oxide layer. The layers may be formed by conformal or non-conformal deposition. The transparent conductive oxide layer may include a material selected from doped zinc oxide, indium tin oxide, cadmium tin oxide (Cd₂SnO₄), zinc stannate (Zn₂SnO₄), and doped titanium dioxide (TiO₂). In one or more embodiments, the anode contact layer 50 can include a layer stack including an adhesion metal layer (e.g., platinum layer, nickel layer, etc.) and a silver layer. The anode contact layer 50 may be formed, for example, by physical vapor deposition.

FIG. 6C is a vertical cross-sectional view of an exemplary intermediate structure including micro-LEDs 12 on the LED die base layer 15, according to one or more embodiments.

The micro-LEDs 12 may be formed by forming a photoresist layer on the anode contact layer 50, and lithographically patterning the photoresist layer to cover each discrete area that corresponds to the area of a micro-LED 12. The photoresist layer can include a two-dimensional array of discrete portions that are laterally spaced apart from each other. For example, two sets of line trenches extending along orthogonal horizontal directions can be provided among the patterned portions of the photoresist layer.

An anisotropic etch process that may include multiple etch steps can be performed to etch through unmasked portions of the anode contact layer 50, the p-doped semiconductor material layer 36, the active region 34, the n-doped compound semiconductor region 32, and optionally the n-doped compound semiconductor substrate layer 26 and/or the single crystalline buffer semiconductor layer 24. The multiple etch steps can be employed to etch through the various material portions. Each of the anode contact layer 50, the p-doped semiconductor material layer 36, the active region 34, the n-doped compound semiconductor region 32, and optionally the n-doped compound semiconductor substrate layer 26 and/or the single crystalline buffer semiconductor layer 24 may be divided into multiple discrete portions that underlie a respective one of the patterned portions of the photoresist layer. Thus, the stack of the anode contact layer 50, the p-doped semiconductor material layer 36, the active region 34, the n-doped compound semiconductor region 32, and optionally the n-doped compound semiconductor substrate layer 26 and/or the single crystalline buffer semiconductor layer 24 may be patterned by a combination of a lithographic process and an anisotropic etch process.

Each continuous set of remaining portions of the anode contact layer 50, the p-doped semiconductor material layer 36, the active region 34, the n-doped compound semiconductor region 32, and optionally the n-doped compound semiconductor substrate layer 26 and/or the single crystalline buffer semiconductor layer 24 may constitute components of a respective micro-LED 12. The sidewalls of the n-doped compound semiconductor substrate layer 26 and the single crystalline buffer semiconductor layer 24 of each light emitting diode 10 can be formed with a finite taper angle due to the less than infinite selectivity of the anisotropic etch process that is employed to etch the materials of the n-doped compound semiconductor substrate layer 26 and the single crystalline buffer semiconductor layer 24. The taper angle can be in a range from 1 degree to 15 degrees, such as from 2 degrees to 10 degrees and/or from 3 degrees to 6 degrees, although lesser and greater taper angles can also be employed.

The LED die base layer 15 may also be separated into sections, with each section including a group of four (4) adjacent micro-LEDs 12 (e.g., see FIG. 1D). The LED die base layer 15 may be separated, for example, concurrently with the forming of the micro-LEDs 12 That is, the LED die base layer 15 may be separated by the same photolithographic process used to form the micro-LEDs 12. Alternatively, the LED die base layer 15 may be separated before or after forming of the micro-LEDs 12 by a photolithographic process similar to the photolithographic process used to form the micro-LEDs 12.

FIG. 6D is another vertical cross-sectional view of an exemplary intermediate structure including micro-LEDs 12 on the LED die base layer 15, according to one or more embodiments. If the anode contact layer 50 is not reflective, then an optional reflective metal layer 70 can be formed on the anode contact layer 50. In some configurations, the reflective metal layer 70 may be formed as a planar structure that entirely overlies the top surface of an underlying anode contact layer 50. In such configurations, the entirety of the reflective material layer 70 is more distal from the n-doped compound semiconductor substrate layer 26 than a most distal surface of the n-doped compound semiconductor region 32 is from the n-doped compound semiconductor substrate layer 26. In such embodiments, the reflective material layer 70 may have a smaller area than the anode contact layer 50.

Alternatively, the reflective metal layer 70 may be formed with a laterally-extending portion that is more distal from the n-doped compound semiconductor substrate layer 26 than a most distal surface of the p-doped semiconductor material layer 36 (which is in contact with an anode contact layer 50) is from the n-doped compound semiconductor substrate layer 26, and a sidewall portion adjoined to a periphery of the laterally-extending portion, extending downward therefrom, and laterally surrounding the n-doped compound semiconductor region 32, the n-doped compound semiconductor substrate layer 26, and the single crystalline buffer semiconductor layer 24. Generally, the reflective material layer 70 can be patterned to provide a suitable lateral extent for each micro-LED 12. A combination of a photolithographic patterning and an etch process (such as an anisotropic etch process or an isotropic etch process) can be employed.

Bonding pads 80 including an underbump metallurgy (UBM) layer stack can be formed on each reflective material layer 70 (or on each anode contact layer 50 in case the reflective material layer 70 is not employed). The UBM layer stack can include any metallic layer stack known in the art that can be employed as a bonding pad structure that enables attachment of a solder material thereupon. The solder material portion 90 can be formed on the bonding pad 80 by a suitable process, such as electroplating.

FIG. 6E is vertical cross-sectional view of an exemplary intermediate structure including the LED die 10 being separated from the substrate 22, according to one or more embodiments. The LED die 10 is placed in contact with the backplane 110 such that the solder material portion 90 on the micro-LEDs 12 may be facing the backplane 110 and contact the bonding pads 112. In particular, the four (4) solder material portions 90 on the four (4) micro-LEDs 12 of the LED die 10 may contact four (4) bonding pads 112, respectively. The solder material portion 90 may then be reflowed so that micro-LEDs 12 of the LED die 10 are bonded by the solder material portion 90 to the bonding pads 112, respectively. The reflow may be performed by heating the solder material portion 90 by irradiating by an infrared laser beam through the LED dies 10 onto the solder material portion 90. The reflow may alternatively be performed by annealing the light emitting device 10 in a furnace or similar heating apparatus above the melting temperature of the solder material portion 90.

A laser lift-off process is performed to separate each bonded LED die 10 from the substrate 22. In the laser lift-off process, ultraviolet laser radiation 600 may be irradiated through the substrate 22 to an interface between the LED die 10 and the substrate 22. The laser radiation 600 may heat a portion of the LED die base 15 (e.g., a GaN layer) at the interface between the LED die 10 and the substrate 22, causing the LED die 10 to be released from the substrate 22. The laser lift-off may be performed before or after bonding the LED die 10 to the backplane 110. If the laser lift-off is performed before bonding the LED die 10 to the backplane 110, then the LED die 10 may be clamped to the backplane by any clamping device.

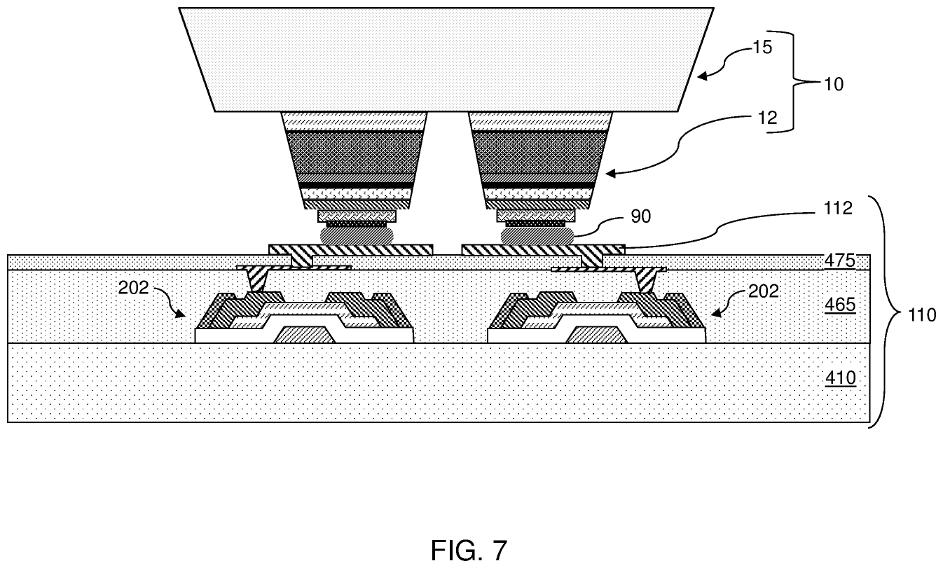

FIG. 7 is vertical cross-sectional view of an exemplary intermediate structure including the LED die 10 mounted on the backplane 110 after removing the substrate 22, according to one or more embodiments. The method of transferring the LED dies 10 from the substrate 22 to the backplane 110 may be substantially the same for both the RGB LED dies 10 in the alternative layout pattern of FIG. 4 and the single-color LED dies 10 in FIG. 1A.

Referring again to FIG. 1C, after the LED dies 10 are mounted on the backplane 110, the dielectric material layer 150 may be formed in the gaps between the backplane 110 and the LED dies 10. The dielectric material layer 150 may be formed so as to substantially embed the LED dies 10 in the dielectric material layer 150. The dielectric material layer 150 may be formed, for example, by a suitable deposition process, such as spin coating.

The n-type contact layer 160 (e.g., shared cathode) may then be formed on the substantially coplanar surface 15S₁ of the LED die base layer 15 and surface of the dielectric material layer 150. The n-type contact layer 160 may be formed by a suitable process including, for example, MOVPE, MBE, HVPE, LPE, MOMBE, and ALD. The frame 170 (e.g., metal frame) may then be formed around an outer periphery of the light emitting device 100 to complete the fabrication of the light emitting device 100.

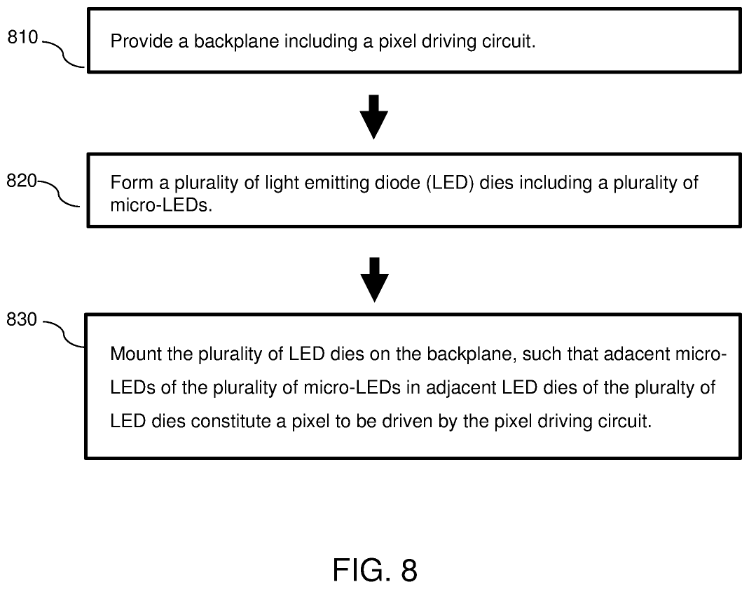

FIG. 8 is a flow chart illustrating a method of making the light emitting device 100 according to one or more embodiments. Step 810 includes providing a backplane including a pixel driving circuit. Step 820 includes forming a plurality of light emitting diode (LED) dies 10 including a plurality of micro-LEDs 12. Step 830 includes mounting the plurality of LED dies 10 on the backplane 110, such that adjacent micro-LEDs 12 of the plurality of micro-LEDs in adjacent LED dies 10 of the plurality of LED dies constitute a pixel 130 to be driven by the pixel driving circuit.

In one embodiment, the light emitting device 100 comprises a display device containing a plurality of the pixels 130. The pixel driving circuit is configured to drive the pixels to form an image in the display device.

Referring again to FIGS. 2A-3B, another aspect of the present disclosure is directed to a computer program product which may include, for example, a computer readable storage medium (hereinafter, the “storage medium”) that may store computer readable program instructions (hereinafter, the “computer program” or “instructions”) for performing the features and functions of the defective micro-LED detector 310, processing device 320, the memory device 330 or the display module 340. The computer readable storage medium may store the instructions thereon for causing the processing device 320 (e.g., computer, instruction execution device, computing device, computer processor, central processing unit (CPU), microprocessor, etc.) to perform a feature or function of the present disclosure. That is, at least one embodiment may include a programmable storage medium tangibly embodying a program of machine-readable instructions executable by a digital processing apparatus to perform the method of repairing a defective micro-LED, the method including detecting a defective micro-LED in a pixel array, identifying a redundant micro-LED associated with the defective micro-LED, and activating the redundant micro-LED in place of the defective micro-LED.

The computer readable storage medium can be a tangible device that can retain and store the instructions for execution by the processing device 320. The computer readable storage medium may be, for example, but is not limited to, an electronic storage device, a magnetic storage device, an optical storage device, an electromagnetic storage device, a semiconductor storage device, or any suitable combination of the foregoing.

A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing.

The computer readable storage medium, as used herein, should not be construed as merely being a “transitory signal” such as a radio wave or other freely propagating electromagnetic wave, an electromagnetic wave propagating through a waveguide or other transmission media (e.g., light pulses passing through a fiber-optic cable), or an electrical signal transmitted through a wire. The processing device 320 can access the instructions on the computer readable storage medium. Alternatively, the processing device 320 can access (e.g., download) the instructions from an external computer or external storage device via a network such as the Internet, a local area network, a wide area network and/or a wireless network.

The network may include, for example, copper transmission cables, optical transmission fibers, wireless transmission, routers, firewalls, switches, gateway computers and/or edge servers. For example, the processing device 320 may include a network adapter card or network interface which receives the instructions from the network and forwards the instructions to the computer readable storage medium within the processing device which stores the instructions.

The instructions for performing the features and functions of the present disclosure may include, for example, assembler instructions, instruction-set-architecture (ISA) instructions, machine instructions, machine dependent instructions, microcode, firmware instructions, state-setting data, or either source code or object code written in one or more programming languages (or combination of programming languages), including an object oriented programming language such as Java, Smalltalk, C++ or the like, and conventional procedural programming languages, such as the “C” programming language or similar programming languages.

The instructions may execute entirely on the processing device 320 (e.g., a user's computer), partly on the processing device 320, as a stand-alone software package, partly on the processing device 320 and partly on a remote computer or entirely on the remote computer or a server. For example, the instructions may execute on a remote computer which is connected to the processing device (e.g., user's computer) through a network such as a local area network (LAN) or a wide area network (WAN), or may execute on an external computer which is connected to the processing device 320 through the Internet using an Internet Service Provider.

The processing device 320 may include, for example, electronic circuitry including, for example, programmable logic circuitry, field-programmable gate arrays (FPGA), or programmable logic arrays (PLA) that may execute the instructions by utilizing state information of the instructions to personalize the electronic circuitry, in order to perform a feature or function of the present disclosure.

It should be noted that the features and functions of the embodiments of the present disclosure which are described above with reference to FIGS. 2A-3B may be implemented by the processing device 320 executing the instructions. That is, each block of the flowchart illustrations and/or block diagrams, and combinations of blocks in the flowchart illustrations and/or block diagrams, can be implemented by processing device 320 executing the instructions.

The instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

That is, the instructions may be executed by the processing device 320 to cause a series of operational steps to be performed by the processing device 320 to produce a computer-implemented process, so that the executed instructions implement the features/functions/acts described above with respect to the flowchart and/or block diagram block or blocks of FIGS. 2A-3B. Thus, the flowchart and block diagrams in the FIGS. 2A-3B illustrate not only a method, system, apparatus or device, but also illustrate the architecture, functionality, and operation of the processing device 320 executing the instructions. In this regard, each block in the flowchart or block diagrams may represent a module, segment, or portion of the instructions, which includes one or more executable instructions for implementing the specified logical function(s).

In some alternative implementations, the features or functions in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following claims and the principles and novel features disclosed herein.

1. A light emitting device, comprising:
a backplane;
a plurality of light emitting diode (LED) dies mounted on the backplane, wherein each of the LED dies comprising a plurality of LEDs; and
a pixel comprising adjacent micro-LEDs of the plurality of LEDs located in adjacent LED dies of the plurality of LED dies.

2. The light emitting device of claim 1, wherein the plurality of LEDs comprise a plurality of micro-LEDs having at least one of a length or a width of 20 microns of less which function as subpixels of the pixel.

3. The light emitting device of claim 2, wherein:
the adjacent micro-LEDs comprise of the pixel four adjacent micro-LEDs and the adjacent LED dies comprise four adjacent LED dies; and
the four adjacent micro-LEDs comprise micro-LEDs located at adjacent corners of the four adjacent LED dies, respectively.

4. The light emitting device of claim 3, wherein the four adjacent micro-LEDs comprise a two red micro-LEDs, a green micro-LED and a blue micro-LED.

5. The light emitting device of claim 3, wherein the four adjacent micro-LEDs comprise a two green micro-LEDs, a red micro-LED and a blue micro-LED.

6. The light emitting device of claim 2, wherein:
each of the plurality of LED dies comprises a first conductivity type semiconductor layer;
a common transparent cathode electrode is electrically connected to the first conductivity type semiconductor layers of the plurality of LED dies;
the plurality of micro-LEDs comprises a plurality of mesas formed on the first conductivity type semiconductor layer; and
each of the plurality of mesas comprises a second conductivity type semiconductor layer and a light emitting active region located between the first and the second conductivity type semiconductor layers.

7. The light emitting device of claim 6, wherein the backplane comprises a plurality of bonding pads and the plurality of micro-LEDs plurality of LED dies are bonded to the plurality of bonding pads.

8. The light emitting device of claim 7, wherein the plurality of LED dies comprises:
a plurality of red LED dies comprising a plurality of red micro-LEDs;
a plurality of green LED dies comprising a plurality of green micro-LEDs; and
a plurality of blue LED dies comprising a plurality of blue micro-LEDs.

9. The light emitting device of claim 8, wherein the plurality of LED dies are bonded to the plurality of bonding pads in the form of an array comprising:
a first row including the plurality of red LED dies alternatingly formed with the plurality of blue LED dies; and
a second row including the plurality of green LED dies alternatingly formed with the plurality of red LED dies.

10. The light emitting device of claim 9, wherein the adjacent micro-LEDs in the pixel comprise:
a red micro-LED in the plurality of red LED dies in the first row;
a blue micro-LED in the plurality of blue LED dies in the first row;
a green micro-LED in the plurality of green LED dies in the second row; and
a red micro-LED in the plurality of red LED dies in the second row.

11. The light emitting device of claim 9, wherein the adjacent micro-LEDs in the pixel comprise:
a green micro-LED in the plurality of green LED dies in the second row;
a red micro-LED in the plurality of red LED dies in the second row;
a red micro-LED in the plurality of red LED dies in the third row; and
a blue micro-LED in the plurality of blue LED dies in the third row.

12. The light emitting device of claim 7, wherein:
the light emitting device comprises a display device containing a plurality of the pixels; and
the backplane further comprises a pixel driving circuit configured to drive the pixels to form an image.

13. The light emitting device of claim 2, wherein the backplane further comprises:
a defective micro-LED detector that detects a defective micro-LED of the plurality of micro-LEDs; and
a processing device that re-directs a signal for activating the defective micro-LED to a redundant micro-LED having the same color as the defective micro-LED, based on a signal from the defective micro-LED detector.

14. The light emitting device of claim 13, wherein the redundant micro-LED is included in the same pixel as the defective micro-LED.

15. A method of forming a light emitting device, comprising:
providing a backplane;
providing a plurality of light emitting diode (LED) dies, each comprising a plurality of LEDs; and
mounting the plurality of LED dies on the backplane such that adjacent LEDs of the plurality of LEDs in adjacent LED dies of the plurality of LED dies constitute a pixel.

16. The method of claim 15, wherein the plurality of LEDs comprise a plurality of micro-LEDs having at least one of a length or a width of 20 microns of less which function as subpixels of the pixel.

17. The method of claim 16, wherein the mounting of the plurality of LED dies comprises mounting the plurality of LED dies such that the adjacent LED dies comprise four adjacent LED dies, and the adjacent micro-LEDs comprise four adjacent micro-LEDs located at adjacent corners of the four adjacent LED dies, respectively.

18. The method of claim 16, wherein the providing of the plurality of LED dies comprises:
providing a plurality of red LED dies comprising a plurality of red micro-LEDs;
providing a plurality of green LED dies comprising a plurality of green micro-LEDs; and
providing a plurality of blue LED dies comprising a plurality of blue micro-LEDs.

19. The method of claim 16, wherein:
each of the plurality of LED dies comprises a first conductivity type semiconductor layer;
the plurality of micro-LEDs comprises a plurality of mesas formed on the first conductivity type semiconductor layer; and
each of the plurality of mesas comprises a second conductivity type semiconductor layer and a light emitting active region located between the first and the second conductivity type semiconductor layers.

20. The method of claim 19, further comprising:
bonding the plurality of micro-LEDs plurality of LED dies are to a respective plurality of bonding pads located on the backplane; and
forming a common transparent cathode electrode on the first conductivity type semiconductor layers of the plurality of LED dies.
